(19) United States
(12) Patent Application Publication
(10) Pub. No.: US 2005/0201132 A1
(43) Pub. Date: Sep. 15, 2005

(54) Content addressable memory (CAM) cell for operating at a high speed

(75) Inventors: Ho-Geun Shin, Suwon-si (KR); Uk-Rae Cho, Suwon-si (KR); Jong-Soo Seo, Hwaseong-gun (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/069,719

(22) Filed: Mar. 1, 2005

(30) Foreign Application Priority Data
Mar. 12, 2004 (KR) 2004-16797

(51) Int. Cl. G11C 15/00

(52) U.S. Cl. 365/49

(57) ABSTRACT

Provided is a content addressable memory (CAM) cell for operating at a high speed. The CAM cell includes a bit line pair consisting of a bit line and an inverted bit line, first and second memory cells, a match line, and first and second comparators. The first memory cell includes a first storage unit for storing data and first connectors for connecting the bit line pair to the first storage unit and for transmitting data input through the bit line pair to the first storage unit. The second memory cell includes a second storage unit for storing data and second connectors for connecting the bit line pair to the second storage unit and for transmitting the data input through the bit line pair to the second storage unit. The first comparator is connected to the match line and the first storage unit and connects the match line to a first voltage or disconnects the match line from the first voltage in response to search data input through a search line and the data stored in the first storage unit. The second comparator is connected to the match line and the second storage unit and connects the match line to the first voltage or disconnects the match line from the first voltage in response to the search data input through an inverted search line and the data stored in the second storage unit.

### CROSS-REFERENCE TO RELATED APPLICATION

This application claims priority to Korean Patent Application No. 2004-16797, filed on Mar. 12, 2004, in the Korean Intellectual Property Office, the disclosure of which is incorporated herein in its entirety by reference.

### FIELD OF THE INVENTION

The present invention relates to a content addressable memory (CAM), and more particularly, to a CAM cell for operating at a high speed.

### DESCRIPTION OF THE RELATED ART

A random access memory (RAM) or a read only memory (ROM) uses an address to indicate a location in an internal memory cell array and can output storage data corresponding to the indicated address. A content addressable memory (CAM) receives external data, compares the received data with data stored in the CAM to determine whether the external data matches the stored data, and outputs an address of stored data matching the external data.

Each cell of a CAM includes a comparison logic circuit. Data input to the CAM is compared with data stored in all of its cells and an address is output representing a matching result. A CAM is widely used for rapidly searching patterns, lists, image data and so forth.

Types of CAMs include binary CAMs and ternary CAMs (TCAM). A general binary CAM includes a RAM cell for storing one of two logic states, e.g., “1” and “0”. The binary CAM has a comparison circuit that compares external data (e.g., search data) with data stored in the RAM cell and, when the search data matches the stored data, sets a corresponding match line to a specific logic state.

Examples of binary CAMs are disclosed in U.S. Pat. Nos. 4,646,271, 4,780,845, 5,490,102 and 5,495,382. The TCAM can store three logic states, e.g., “1”, “0” and “don't care”. An example of a TCAM is disclosed in U.S. Pat. No. 5,319,590.

FIG. 1 is a circuit diagram of a general TCAM cell 100. Referring to FIG. 1, the TCAM cell 100 includes static random access memory (SRAM) cells 10 and 20 for storing data, and comparison circuits 71 and 72. The SRAM cell 10 includes a latch including two inverters 21 and 22, and first and second transistors 31 and 32 including gates connected to a wordline WL1. The first and second transistors 31 and 32 transmit data from data lines D and /D to the latch. Similarly, the SRAM cell 20 includes a latch including two inverters 51 and 52, and third and fourth transistors 61 and 62 including gates connected to a wordline WL2. The third and fourth transistors 61 and 62 transmit the data from the data lines D and /D to the latch.

The comparison circuit 71 includes first and second comparison transistors 81 and 82, which are serially connected. A drain of the first comparison transistor 81 is connected to a match line 43, and a source of the second comparison transistor 82 is grounded. A gate of the first comparison transistor 81 is connected to the inverted data line /D, and a gate of the second comparison transistor 82 is connected to the output of the inverter 22 of the SRAM cell 10.

The comparison circuit 72 includes third and fourth comparison transistors 91 and 92 which are serially connected. A drain of the third comparison transistor 91 is connected to the match line 43, and a source of the fourth comparison transistor 92 is grounded. A gate of the third comparison transistor 91 is connected to the data line D, and a gate of the fourth comparison transistor 92 is connected to the output of the inverter 51 of the SRAM cell 20.

In the TCAM cell 100, search data, which is to be compared to stored data, is transmitted through the data line pair D and /D. The data line pair D and /D is, for example, a bit line for transmitting data and a search line for transmitting the search data integrated into one line.

A write operation of the TCAM cell 100 will now be explained. Data transmitted through the data line pair D and /D is sequentially stored in the SRAM cells 10 and 20 according to the wordlines WL1 and WL2, which are alternately activated. Specifically, when data is transmitted through the data line pair D and /D, the wordline WL1 is turned on so that the transmitted data is stored in the SRAM cell 10. When additional data is transmitted through the data line pair D and /D, the wordline WL2 is turned on to store the additional data in the SRAM cell 20.

The search data is then transmitted through the data line pair D and /D. The comparison circuits 71 and 72 compare the search data with the data stored in the SRAM cells 10 and 20 and set a logic level of the match line 43 depending on the comparison result.

In the TCAM cell 100, the transistors 31, 32, 61 and 62 of the SRAM cells 10 and 20 are directly connected to the data line pair D and /D, and the first and third comparison transistors 81 and 91 are also directly connected to the data line pair D and /D. As the number of transistors directly connected to the data line pair D and /D increases, the load of the data line pair D and /D increases. When the data line pair D and /D has a large load, data write and read operation speeds are low. Furthermore, because the first and third comparison transistors 81 and 91 of the comparison circuits 71 and 72 are directly connected to the data line pair D and /D, the voltage level of the match line 43 fluctuates.

For example, if the match line 43 is precharged to a logic high level, data “0” is stored in the SRAM cell 10, and search data “1” is transmitted through the inverted data line /D. The logic level of the match line 43 should remain constant before comparison because both of the first and second comparison transistors 81 and 82 of the comparison circuit 71 are not turned on. However, during the comparison, the first comparison transistor 81 is turned on by the search data transmitted through the inverted data line /D and the voltage level of the match line 43 is fluctuated by the turned-on first comparison transistor 81.

As described above, the conventional TCAM cell 100 can have many transistors connected to the data line pair D and /D such that the load of the data line pair D and /D is high. Accordingly, data write and read operation speeds are low and the voltage level of the match line 43 fluctuates during a comparison operation of the TCAM cell 100.

A need therefore exists for a CAM cell and a memory array including the CAM cell whose operating speed is improved by separating a comparison operation from data read and writing operations.

### SUMMARY OF THE INVENTION

According to an aspect of the present invention, there is provided a content addressable memory (CAM) cell comprising a bit line pair consisting of a bit line and an inverted bit line, a first memory cell, a second memory cell, a match line, a first comparator, and a second comparator.

The first memory cell includes a first storage unit for storing data and first connectors for connecting the bit line pair to the first storage unit and for transmitting data input through the bit line pair to the first storage unit.

The second memory cell includes a second storage unit for storing data and second connectors for connecting the bit line pair to the second storage unit and for transmitting the data input through the bit line pair to the second storage unit.

The first comparator is connected to the match line and the first storage unit and connects the match line to a first voltage or disconnects the match line from the first voltage in response to search data input through a search line and the data stored in the first storage unit.

The second comparator is connected to the match line and the second storage unit and connects the match line to the first voltage or disconnects the match line from the first voltage in response to the search data input through an inverted search line and the data stored in the second storage unit.

According to another aspect of the present invention, there is provided a CAM cell comprising a bit line pair consisting of a bit line and an inverted bit line through which data is transmitted, first and second wordlines, a match line, a search line pair consisting of a search line and an inverted search line through which search data is transmitted, first and second memory cells, and first and second comparators.

The first and second memory cells are respectively connected to the first and second wordlines and the bit line pair and store the data transmitted through the bit line pair when the first and second wordlines are activated, respectively.

The first and second comparators are connected to the first and second memory cells, the search line pair and the match line and connect the match line to a first voltage or disconnect the match line from the first voltage in response to the data stored in the first and second memory cells and the search data transmitted through the search line pair.

The first and second comparators disconnect the match line from the first voltage when the data transmitted through the bit line matches the search data transmitted through the search line.

The first and second comparators connect the match line to the first voltage when the data transmitted through the bit line does not match the search data transmitted through the search line.

According to another aspect of the present invention, there is provided a memory array comprising N bit line pairs disposed in a column and M address line pairs disposed in a row, and N×M memory cells respectively connected to the N bit line pairs and the M address line pairs. Each of the memory cells receives data from the bit line pair to which it is connected.

Each of the memory cells comprises first and second wordlines connected to each address line pair, a match line, a search line pair consisting of a search line and an inverted search line through which search data is transmitted, first and second memory cells, and first and second comparators.

The first and second memory cells are respectively connected to the first and second wordlines and the bit line pair and store the data transmitted through the bit line pair when the first and second wordlines are activated respectively.

The first and second comparators are connected to the first and second memory cells, the search line pair and the match line and connect the match line to a first voltage or disconnect the match line from the first voltage in response to the data stored in the first and second memory cells and the search data transmitted through the search line pair.

### BRIEF DESCRIPTION OF THE DRAWINGS

The above and other features of the present invention will become more apparent by describing in detail exemplary embodiments thereof with reference to the attached drawings in which:

FIG. 1 is a circuit diagram of a conventional ternary content addressable memory (TCAM) cell;

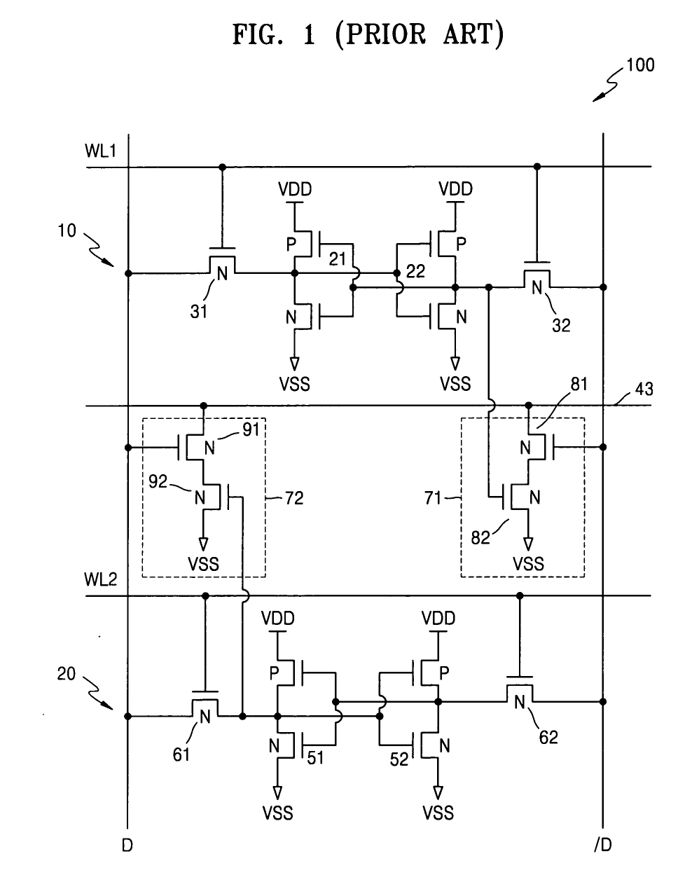

FIG. 2 is a circuit diagram of a CAM cell according to an exemplary embodiment of the present invention; and

FIG. 3 is a table illustrating the operation of the CAM cell shown in FIG. 2.

### DETAILED DESCRIPTION OF EXEMPLARY EMBODIMENTS OF THE INVENTION

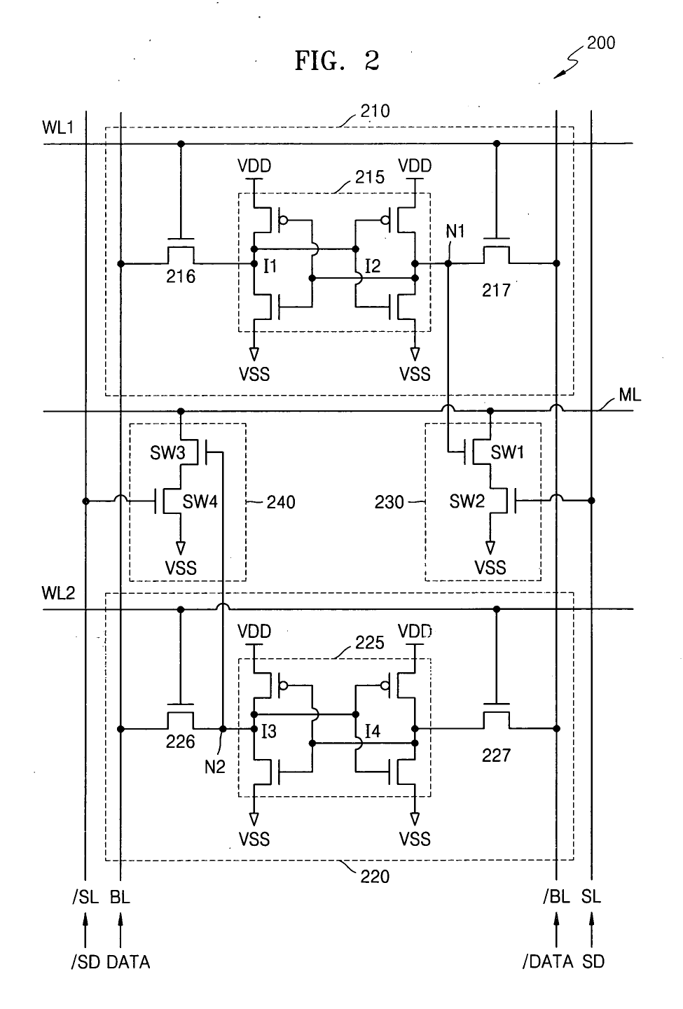

FIG. 2 is a circuit diagram of a content addressable memory (CAM) cell 200 according to an exemplary embodiment of the present invention. Referring to FIG. 2, the CAM cell 200 includes a bit line pair consisting of a bit line BL and an inverted bit line /BL, a first memory cell 210, a second memory cell 220, a match line ML, a first comparator 230 and a second comparator 240.

The first memory cell 210 includes a first storage unit 215 for storing data DATA and inverted data /DATA and first connectors 216 and 217. The first connector 216 connects the bit line BL to the first storage unit 215 and transmits the data DATA input through the bit line BL to the first storage unit 215. The first connector 217 connects the inverted bit line /BL to the first storage unit 215 and transmits the inverted data /DATA input through the inverted bit line /BL to the first storage unit 215.

More specifically, the first storage unit 215 includes first and second inverters I1 and I2 constituting a latch. The first connector 216 connects the first inverter I1 to the bit line BL and the first connector 217 connects the second inverter I2 to the inverted bit line /BL.

The second memory cell 220 includes a second storage unit 225 for storing the data DATA and second connectors 226 and 227. The second connector 226 connects the bit line BL to the second storage unit 225 and transmits the data DATA input through the bit line BL to the second storage unit 225. The second connector 227 connects the inverted bit line /BL to the second storage unit 225 and transmits the inverted data /DATA input through the inverted bit line /BL to the second storage unit 225.

More specifically, the second storage unit 225 includes third and fourth inverters I3 and I4 constituting a latch. The second connector 226 connects the third inverter I3 to the bit line BL and the second connector 227 connects the fourth inverter I4 to the inverted bit line /BL.

The first comparator 230 is connected to the match line ML and the first storage unit 215. The first comparator 230 connects the match line ML to a predetermined first voltage VSS or disconnects the match line ML from the first voltage VSS in response to search data SD input through a search line SL and the data stored in the first storage unit 215.

More specifically, the first comparator 230 includes first and second switching elements SW1 and SW2 serially connected between the match line ML and the first voltage VSS. The first switching element SW1 has a first control input connected to the first storage unit 215 and the second switching element SW2 has a second control input connected to the search line SL.

The second comparator 240 is connected to the match line ML and the second storage unit 225. The second comparator 240 connects the match line ML to the first voltage VSS or disconnects the match line ML from the first voltage VSS in response to inverted search data /SD input through an inverted search line /SL and the data stored in the second storage unit 225.

More specifically, the second comparator 240 includes third and fourth switching elements SW3 and SW4 serially connected between the match line ML and the first voltage VSS. The third switching element SW3 has a third control input connected to the second storage unit 225 and the fourth switching element SW4 has a fourth control input connected to the inverted search line /SL.

The first voltage VSS is a ground voltage. The first connectors 216 and 217 are connected to a first wordline WL1 while the second connectors 226 and 227 are connected to a second wordline WL2. The first and second storage units 215 and 225 include metal oxide semiconductor (MOS) transistors.

The configuration and operation of the CAM cell 200 according to the exemplary embodiment of the present invention will now be explained in more detail.

As further shown in FIG. 2, the CAM cell 200 includes a separate data transmission line and a search data transmission line. More specifically, the data DATA and the inverted data /DATA are transmitted through the bit line pair BL and /BL while the search data SD and the inverted search data /SD are transmitted through the search line pair SL and /SL.

The bit line pair BL and /BL through which data write and read operations are carried out is also separate from the search line pair SL and /SL through which a comparison operation is performed. Because the number of transistors connected to the bit line pair BL and /BL is small, the load of the bit line pair BL and /BL is reduced. Thus, the data read and writing operation speeds of the CAM cell 200 are increased.

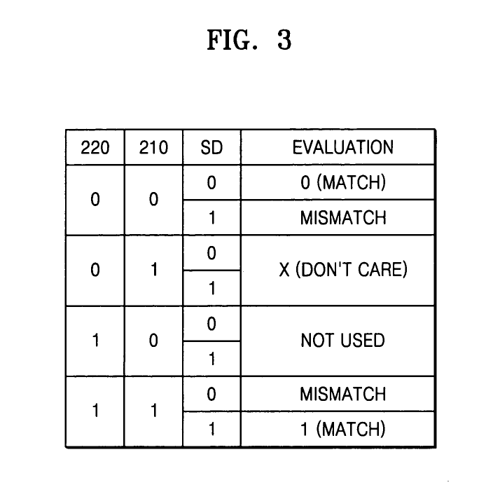

FIG. 3 is a table for explaining the operation of the CAM cell 200 shown in FIG. 2. The operation of the CAM cell 200, which can, for example, prevent the voltage level of the match line ML from fluctuating, will now be described with reference to FIGS. 2 and 3.

The data DATA and the inverted data /DATA which are to be stored in the first memory cell 210 are transmitted through the bit line pair BL and /BL. When the wordline WL1 is activated to a high level, the first connectors 216 and 217 are turned on. The first connectors 216 and 217 are negative channel metal oxide semiconductor (NMOS) transistors including gates connected to the wordline WL1.

When the first connectors 216 and 217 are turned on, the data DATA and the inverted data /DATA transmitted through the bit line pair BL and /BL are stored in the first storage unit 215 including the first and second inverters I1 and I2, and the wordline WL1 is inactivated.

Next, the data DATA and the inverted data /DATA which are to be stored in the second memory cell 220 are transmitted through the bit line pair BL and /BL. When the wordline WL2 is activated to a high level, the second connectors 226 and 227 are turned on. The second connectors 226 and 227 are NMOS transistors including gates connected to the wordline WL2.

When the second connectors 226 and 227 are turned on, the data DATA and the inverted data /DATA transmitted through the bit line pair BL and /BL are stored in the second storage unit 225 including the third and fourth inverters I3 and I4 and the wordline WL2 is inactivated.

The searching and comparing operations of the CAM cell 200 will now be explained.

The search data SD and the inverted search data /SD are transmitted through the search line pair SL and /SL when the voltage level of the match line ML is precharged to a high level. While the voltage level of the match line ML is initially precharged to a high level in the above-described exemplary embodiment, the voltage level of the match line ML can be precharged to a low level in another exemplary embodiment of the present invention.

If the search data SD does not match the stored data DATA, the logic level of the match line ML is varied. For example, the logic level of the match line ML is changed to a low level when the search data SD and the stored data DATA do not match each other. However, the logic level of the match line ML is maintained at a high level when the search data SD matches the stored data DATA.

For example, if “0” and “1” are respectively applied to the bit line BL and the inverted bit line /BL when the wordline W1 is activated such that “0” is stored in the first memory cell 210, and “0” and “1” are respectively applied to the bit line BL and the inverted bit line /BL when the wordline W2 is activated such that “0” is stored in the second memory cell 220. In addition, if “0” is transmitted through the search line SL and “1” is transmitted through the inverted search line /SL. Then, a first node N1 of the first storage unit 215 has a logic value equal to “1” and a second node N2 of the second storage unit 225 has a logic value equal to “0”.

The first and second switching elements SW1 and SW2 of the first comparator 230 are NMOS transistors. The gate of the first switching element SW1 is controlled by the first control input. The first control input is a logic value output from the first node N1. The gate of the second switching element SW2 is controlled by the second control input. The second control input is a logic value of the search data SD output from the search line SL.

Because the logic value of the first node N1 is “1” and the search data SD is “0”, the first switching element SW1 is turned on while the second switching element SW2 is turned off. Accordingly, the match line ML is not connected to the first voltage VSS, that is, the ground voltage.

The third and fourth switching elements SW3 and SW4 of the second comparator 240 are NMOS transistors. The gate of the third switching element SW3 is controlled by the third control input. The third control input is a logic value output from the second node N2. The gate of the fourth switching element SW4 is controlled by the fourth control input. The fourth control input is a logic value of the inverted search data /SD output from the inverted search line /SL.

Because the logic value of the second node N2 is “0” and the inverted search data /SD is “1”, the fourth switching element SW4 is turned on while the third switching element SW3 is turned off. Accordingly, the match line ML is not connected to the first voltage VSS, that is, the ground voltage. For example, the voltage level of the match line ML is maintained at the initial high voltage such that the search data SD matches the stored data DATA.

If “1” is transmitted through the search line SL and “0” is transmitted through the inverted search line /SL, then the first node N1 of the first storage unit 215 has a logic value equal to “1” and the second node N2 of the second storage unit 225 has a logic value equal to “0”. Then, both of the third and fourth switching elements SW3 and SW4 are turned off while both of the first and second switching elements SW1 and SW2 are turned on. Accordingly, the match line ML is connected to the first voltage VSS, that is, the ground voltage, and the voltage of the match line ML is changed from the initial high voltage to a low voltage such that the search data SD does not match the stored data DATA.

In the CAM cell 200, the search line pair SL and /SL is not directly connected to the first and third switching elements SW1 and SW3 that are directly connected to the match line ML. Thus, the voltage of the match line ML can be prevented from fluctuating in response to the search data SD. Further, the CAM cell 200 and the memory array thereof according to the present invention separately carry out a comparison operation and data read and write operations to improve the operating speed of the CAM cell 200.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A content addressable memory (CAM) cell comprising:
a bit line pair comprising a bit line and an inverted bit line;
a first memory cell comprising a first storage unit for storing data and first connectors for connecting the bit line pair to the first storage unit and for transmitting data input through the bit line pair to the first storage unit;
a second memory cell comprising a second storage unit for storing data and second connectors for connecting the bit line pair to the second storage unit and for transmitting the data input through the bit line pair to the second storage unit;
a match line;
a first comparator connected to the match line and the first storage unit, the first comparator for performing one of connecting the match line to a first voltage and disconnecting the match line from the first voltage in response to search data input through a search line and the data stored in the first storage unit; and
a second comparator connected to the match line and the second storage unit, the second comparator for performing one of connecting the match line to the first voltage and disconnecting the match line from the first voltage in response to the search data input through an inverted search line and the data stored in the second storage unit.

2. The CAM cell as claimed in claim 1, wherein the first storage unit comprises a latch comprising first and second inverters.

3. The CAM cell as claimed in claim 1, wherein the first comparator comprises first and second switching elements serially connected between the match line and the first voltage, the first switching element for receiving a first control input from the first storage unit, the second switching element for receiving a second control input from the search line.

4. The CAM cell as claimed in claim 1, wherein the second comparator comprises third and fourth switching elements serially connected between the match line and the first voltage, the third switching element for receiving a third control input from the second storage unit, the fourth switching element for receiving a fourth control input from the inverted search line.

5. The CAM cell as claimed in claim 1, wherein the first connectors are connected to a first wordline and the second connectors are connected to a second wordline.

6. A content addressable memory (CAM) cell comprising:
a bit line pair comprising a bit line and an inverted bit line through which data is transmitted;
first and second wordlines;
a match line;
a search line pair comprising a search line and an inverted search line through which search data is transmitted;
first and second memory cells respectively connected to the first and second wordlines and the bit line pair, the first and second memory cells for storing the data transmitted through the bit line pair when the first and second wordlines are respectively activated; and
first and second comparators connected to the first and second memory cells, the search line pair and the match line, the first and second comparators for performing one of connecting the match line to a first voltage and disconnecting the match line from the first voltage in response to the data stored in the first and second memory cells and the search data transmitted through the search line pair.

7. The CAM cell as claimed in claim 6, wherein the first and second comparators disconnect the match line from the first voltage when the data transmitted through the bit line matches the search data transmitted through the search line.

8. The CAM cell as claimed in claim 6, wherein the first and second comparators connect the match line to the first voltage when the data transmitted through the bit line does not match the search data transmitted through the search line.

9. The CAM cell as claimed in claim 6, wherein the first memory cell comprises a first storage unit for storing the data and first connectors that are connected to the first wordline to transmit the data input through the bit line pair to the first storage unit, and the second memory cell comprises a second storage unit for storing the data and second connectors that are connected to the second wordline to transmit the data input through the bit line pair to the second storage unit.

10. The CAM cell as claimed in claim 9, wherein the first storage unit comprises a latch comprising first and second inverters, and the second storage unit comprises a latch comprising third and fourth inverters.

11. The CAM cell as claimed in claim 6, wherein the first comparator comprises first and second switching elements serially connected between the match line and the first voltage, the first switching element for receiving a first control input from the first storage unit, the second switching element for receiving a second control input from the search line.

12. The CAM cell as claimed in claim 6, wherein the second comparator comprises third and fourth switching elements serially connected between the match line and the first voltage, the third switching element for receiving a third control input from the second storage unit, the fourth switching element for receiving a fourth control input from the inverted search line.

13. A memory array comprising:
N bit line pairs disposed in a column, and M address line pairs disposed in a row; and
N×M memory cells respectively connected to the N bit line pairs and the M address line pairs,
each of the memory for cells receiving data through one of the N bit line pairs to which the memory cell is connected, and each of the memory cells comprising:
first and second wordlines connected to each of the M address line pairs;
a match line;
a search line pair comprising a search line and an inverted search line through which search data is transmitted;
first and second memory cells respectively connected to the first and second wordlines and one of the bit line pairs, the first and second memory cells for storing the data transmitted through the bit line pair when the first and second wordlines are respectively activated; and
first and second comparators connected to the first and second memory cells, the search line pair and the match line, the first and second comparators for performing one of connecting the match line to a first voltage and disconnecting the match line from the first voltage in response to the data stored in the first and second memory cells and the search data transmitted through the search line pair.

14. The memory array as claimed in claim 13, wherein the first and second comparators disconnect the match line from the first voltage when the data transmitted through a bit line of the bit line pair matches the search data transmitted through the search line.

15. The memory array as claimed in claim 13, wherein the first and second comparators connect the match line to the first voltage when the data transmitted through a bit line of the bit line pair does not match the search data transmitted through the search line.

16. The memory array as claimed in claim 13, wherein the first memory cell comprises a first storage unit for storing the data and first connectors that are connected to the first wordline to apply the data input through the bit line pair to the first storage unit, and the second memory cell comprises a second storage unit for storing the data and second connectors that are connected to the second wordline to transmit the data input through the bit line pair to the second storage unit.

17. The memory array as claimed in claim 16, wherein the first storage unit comprises a latch comprising first and second inverters, and the second storage unit comprises a latch comprising third and fourth inverters.

18. The memory array as claimed in claim 13, wherein the first comparator comprises first and second switching elements serially connected between the match line and the first voltage, the first switching element for receiving a first control input from the first storage unit, the second switching element for receiving a second control input from the search line.

19. The memory array as claimed in claim 13, wherein the second comparator comprises third and fourth switching elements serially connected between the match line and the first voltage, the third switching element for receiving a third control input from the second storage unit, the fourth switching element for receiving a fourth control input from the inverted search line.
